(19) United States
(12) Patent Application Publication
(10) Pub. No.: US 2005/0202251 A1
(43) Pub. Date: Sep. 15, 2005

(54) Functional layers for optical uses based on polythiophenes

(75) Inventors: Andreas Elschner, Mulheim (DE); Udo Guntermann, Krefeld (DE); Friedrich Jonas, Aachen (DE)

Correspondence Address: Norris, McLaughlin & Marcus P.A., 875 Third Avenue, 18th Floor, New York, NY, 10022, US

(73) Assignee: H.C. Starck GmbH, Goslar (DE)

(21) Appl. No.: 11/077,522

(22) Filed: Mar. 10, 2005

(30) Foreign Application Priority Data
Mar. 11, 2004 (DE) 10 2004 012 319.5

(51) Int. Cl. H01B 1/12; B05D 3/00; B05D 5/12

(52) U.S. Cl. 428/419; 428/375; 428/403; 252/500; 427/162; 427/337

(57) ABSTRACT

Transparent functional layers of conductive polymers, their production and their use in optical constructions.

The invention relates to transparent functional layers of electrically conductive polymers, their production and their use in optical constructions.

### BACKGROUND OF THE INVENTION

The optical properties of a body are determined by its shape and its material properties. The relevant material properties for optical systems are the refractive index n and the absorption constant k (cf. Born, Max, Principles of Optics. 6th ed. 1. Optics-Collected works ISBN 0-08-026482-4). The optical properties can be modified by application of functional layers which are made of transparent materials and differ from the carrier in respect of n and/or k at least in parts of the electromagnetic radiation spectrum. On the basis of these differences in n and/or k, reflection of radiation occurs at the interface between the functional layer and carrier. In this context, the Fresnel formulae (cf. Born, Max p. 38 et seq.) describe the distribution of reflected, absorbed and transmitted radiation.

Examples of such optical functional layers are: antireflection layers on optical elements, heat insulation layers on glazing panes cladding layers on glass fibers, interference layers on pearlescent pigments etc.

The economic importance of such optical functional layers is high, since the optical properties of an entire body can be changed relatively easily by these.

Possible transparent optical functional layers are materials which are electrically conductive, e.g. TCO layers (transparent conducting oxides), such as indium tin oxide (ITO) or antimony tin oxide (ATO), or thin metal layers or electrically insulating layers, such as e.g. titanium dioxide, silicon dioxide, cryolite or magnesium fluoride. Deposition of these inorganic layers is carried out by sputtering, reactive sputtering or thermal vapor deposition in vacuo and is therefore involved and cost-intensive.

Inorganic optical functional layers have as disadvantages:
a) high process costs for the deposition, since vacuum installations are necessary,
b) high material costs, in particular for ITO, ATO and metal layers,
c) brittleness of the layers, in particular the metal oxide layers,
d) deposition and/or after-conditioning of the layers takes place at high temperatures of T>200° C.,
e) refractive index of the oxidic layers in the visual spectral range, i.e. in the wavelength range of 400 nm<λ<760 nm, is high (n>1.3) and can be modified only with difficulty.

There has therefore continued to be a need for optical functional layers which have properties which are similar to or better than those of inorganic optical functional layers.

The object of the present invention was therefore to produce optical functional layers which can replace the conventional expensive inorganic optical functional layers, but without having the disadvantages listed above.

### SUMMARY OF THE INVENTION

It has been found, surprisingly, that a transparent layer which has a refractive index of n<1.3 in parts of the visible spectral range and which meets the requirements of an optical functional layer can be produced by application of a solution comprising thiophene monomers and oxidizing agents.

The present invention therefore provides a transparent optical functional layer, characterized in that it has a refractive index of n<1.3 in parts of the visible spectral range, in particular in a wavelength range comprising an interval of at least 50 nm, preferably at least 100 nm, and comprises at least one electrically conductive polymer which comprises at least one polythiophene with recurring units of the general formula (I) 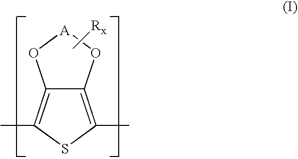
wherein
A represents an optionally substituted C₁-C₅-alkylene radical, preferably an optionally substituted C₂-C₃-alkylene radical,
R represent a linear or branched, optionally substituted C₁-C₁₈-alkyl radical, preferably linear or branched, optionally substituted C₁-C₁₄-alkyl radical, an optionally substituted C₅-C₁₂-cycloalkyl radical, an optionally substituted C₆-C₁₄-aryl radical, an optionally substituted C₇-C₁₈-aralkyl radical, an optionally substituted C₁-C₄-hydroxyalkyl radical, preferably optionally substituted C₁-C₂-hydroxyalkyl radical, or a hydroxyl radical,
x represents an integer from 0 to 8, preferably from 0 to 6, particularly preferably 0 or 1, and
   in the case where several radicals R are bonded to A, these can be identical or different.

The general formula (I) is to be understood as meaning that there are x number of substituent R radicals bonded to the alkylene radical A.

Further electrically conductive polymers which can be employed according to an alternative embodiment of the invention are optionally substituted polypyrroles or optionally substituted polyanilines.

Electrically conductive polymers in the context of the invention are in general polymers with a specific resistance of at most 10⁸ Ω·cm.

In preferred embodiments, the polythiophenes with recurring units of the general formula (I) are those with recurring units of the general formula (Ia) 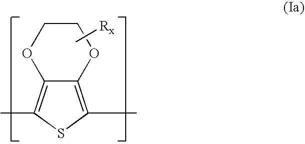
wherein
R and x have the abovementioned meaning.

In further preferred embodiments, the polythiophenes with recurring units of the general formula (I) are those with recurring units of the general formula (Iaa)

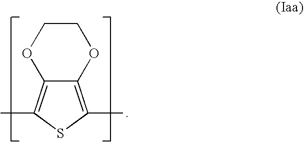

In the context of the invention, the prefix poly- is to be understood as meaning that more than one identical or different recurring unit is contained in the polymer or polythiophene. The polythiophenes contain a total of y recurring units of the general formula (I), wherein y can be an integer from 2 to 2,000, preferably 2 to 100. The recurring units of the general formula (I) can in each case be identical or different within a polythiophene. Polythiophenes with in each case identical recurring units of the general formula (I) are preferred.

The polythiophenes preferably in each case carry H (hydrogen) on the end groups.

In a particularly preferred embodiment, the polythiophene with recurring units of the general formula (I) is poly(3,4-ethylenedioxythiophene), i.e. a homopolythiophene of recurring units of the formula (Iaa).

In a further preferred embodiment of the invention, the functional layer comprises, in addition to the polythiophene of the general formula (I), an anion of a polymeric carboxylic or sulfonic acid as a polymeric anion. This is particularly preferably the anion of polystyrenesulfonic acid.

In the context of the invention, C₁-C₅-alkylene radicals A are: methylene, ethylene, n-propylene, n-butylene or n-pentylene. In the context of the invention, C₁-C₁₈-alkyl represents linear or branched C₁-C₁₈-alkyl radicals, such as, for example, methyl, ethyl, n- or iso-propyl, n-, iso-, sec- or tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl or n-octadecyl, C₅-C₁₂-cycloalkyl represents C₅-C₁₂-cycloalkyl radicals, such as, for example, cyclopentyl, cyclohexyl, cycloheptyl, cyclooctyl, cyclononyl or cyclodecyl, C₅-C₁₄-aryl represents C₅-C₁₄-aryl radicals, such as, for example, phenyl or naphthyl, and C₇-C₁₈-aralkyl represents C₇-C₁₈-aralkyl radicals, such as, for example, benzyl, o-, m-, p-tolyl, 2,3-, 2,4-, 2,5-, 2,6-, 3,4- or 3,5-xylyl or mesityl. The above list serves to explain the invention by way of example and is not to be regarded as a limitation.

Possible optional further substituents of the C₁-C₅-alkylene radicals A are numerous organic groups, for example alkyl, cycloalkyl, aryl, halogen, ether, thioether, disulfide, sulfoxide, sulfone, sulfonate, amino, aldehyde, keto, carboxylic acid ester, carboxylic acid, carbonate, carboxylate, cyano, alkylsilane and alkoxysilane groups as well as carboxamide groups.

The transparent optical functional layer according to the invention can be applied to any desired transparent substrate. Such a substrate can be, for example, glass, extra thin glass (flexible glass) or plastics.

Particularly suitable plastics are: polycarbonates, polyesters, such as e.g. PET and PEN (polyethylene terephthalate or polyethylene-naphthalene dicarboxylate), copolycarbonates, polysulfone, polyether sulfone (PES), polyimide, polyethylene, polypropylene or cyclic polyolefins or cyclic olefin copolymers (COC), hydrogenated styrene polymers or hydrogenated styrene copolymers.

Suitable polymer substrates can be, for example, films, such as polyester films, PES films from Sumitomo or polycarbonate films from Bayer AG (Makrofol®).

An adhesion promoter layer can be located between the substrate and the functional layer. Suitable adhesion promoters are, for example, silanes. Epoxysilanes, such as, for example, 3-glycidoxypropyltrimethoxysilane (Silquest® A187, OSi specialities), are preferred. Other adhesion promoters with hydrophilic surface properties can also be used. Thus e.g. a thin layer of PEDT:PSS (Poly(3,4-ethylenedioxythiophene)poly(styrenesulfonate)) is described as a suitable adhesion promoter for PEDT (poly(3,4-ethylenedioxythiophene)) (Hohnholz et al., Chem. Commun. 2001, 2444-2445).

The polymeric optical functional layer according to the invention has the following advantages over the known inorganic optical functional layers described above:

It is

a) easy to apply from solution to any desired substrate, and expensive deposition processes in vacuo are therefore eliminated,
b) not brittle and therefore also suitable for flexible substrates,
c) it has a low refractive index in the visible spectral range, which can easily be adapted by addition of other transparent polymers.

Production is expediently carried out such that the layer comprising at least one conductive polymer is produced from precursors for the preparation of conductive polymers corresponding to the formula (I) or aniline or pyrrole, optionally in the form of solutions, directly in situ on a suitable substrate by means of chemical oxidative polymerization in the presence of one or more oxidizing agents or by means of electropolymerization. A layer comprising at least one polymeric anion and at least one polythiophene with recurring units of the general formula (I) is applied to this layer, in particular optionally after drying and washing, from a dispersion comprising at least one polymeric anion and at least one polythiophene with recurring units of the general formula (I).

The invention therefore also provides a process for the production of a polymeric optical functional layer according to the invention on a substrate, characterized in that the layer comprising at least one conductive polymer is produced by applying to the substrate precursors for the preparation of conductive polymers, such as pyrrole or aniline or, in particular, a thiophene corresponding to the general formula (II) 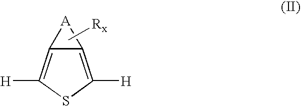
in which A, R and x have the meaning given above for formula (I), optionally in the form of solutions, and chemical oxidative polymerization in the presence of one or more oxidizing agents or electrochemical polymerization is carried out to give the conductive polymers.

Possible suitable substrates are those already mentioned above. The substrate can be treated with an adhesion promoter before application of the layer comprising at least one conductive polymer. Such a treatment can be carried out, for example, by spin-coating, impregnation, pouring, dripping, spraying, atomizing, knife-coating, brushing or printing, for example ink-jet, screen, contact or tampon printing.

Precursors for the preparation of conductive polymers, also called precursors in the following, are understood as meaning corresponding monomers or derivatives thereof. Mixtures of different precursors can also be used. Suitable monomeric precursors are, for example, optionally substituted thiophenes, pyrroles or anilines, preferably optionally substituted thiophenes of the general formula (II) 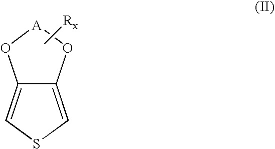
wherein
A, R and x have the abovementioned meaning,
   particularly preferably optionally substituted 3,4-alkylenedioxythiophenes of the general formula (IIa)

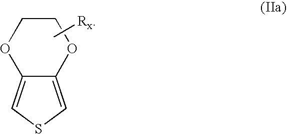

In a preferred embodiment, 3,4-alkylenedioxythiophenes of the formula (IIaa) 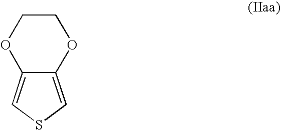
are employed as monomeric precursors.

In the context of the invention, derivatives of these monomeric precursors are understood as meaning, for example, dimers or trimers of these monomeric precursors. Higher molecular weight derivatives, i.e. tetramers, pentamers etc. of the monomeric precursors are also possible as derivatives. The derivatives can be built up from both identical and different monomer units and can be employed in the pure form and in a mixture with one another and/or with the monomeric precursors. Oxidized or reduced forms of these precursors are also included in the term “precursors” in the context of the invention as long as the same conductive polymers are formed during their polymerization as in the case of the precursors described above.

Possible substituents for the precursors, in particular for the thiophenes, preferably for the 3,4-alkylenedioxythiophenes, are the radicals mentioned for R for the general formula (I).

Processes for the preparation of the monomeric precursors for the preparation of conductive polymers and derivatives thereof are known to the expert and are described, for example, in L. Groenendaal, F. Jonas, D. Freitag, H. Pielartzik & J. R. Reynolds, Adv. Mater. 12 (2000) 481-494 and literature cited therein.

The precursors can optionally be employed in the form of solutions. Suitable solvents for the precursors which may be mentioned are, above all, the following organic solvents which are inert under the reaction conditions: aliphatic alcohols, such as methanol, ethanol, i-propanol and butanol; aliphatic ketones, such as acetone and methyl ethyl ketone; aliphatic carboxylic acid esters, such as ethyl acetate and butyl acetate; aromatic hydrocarbons, such as toluene and xylene; aliphatic hydrocarbons, such as hexane, heptane and cyclohexane; chlorohydrocarbons, such as methylene chloride and dichloroethane; aliphatic nitrites, such as acetonitrile; aliphatic sulfoxides and sulfones, such as dimethylsulfoxide and sulfolane; aliphatic carboxylic acid amides, such as methylacetamide, dimethylacetamide and dimethylformamide; and aliphatic and araliphatic ethers, such as diethyl ether and anisole. Water or a mixture of water with the abovementioned organic solvents can furthermore also be used as the solvent.

Further components, such as one or more organic binders which are soluble in organic solvents, such as polyvinyl acetate, polycarbonate, polyvinylbutyral, polyacrylic acid esters, polymethacrylic acid esters, polystyrene, polyacrylonitrile, polyvinyl chloride, polybutadiene, polyisoprene, polyethers, polyesters, silicones and styrene/acrylic acid ester, vinyl acetate/acrylic acid ester and ethylene/vinyl acetate copolymers, or water-soluble binders, such as polyvinyl alcohols, crosslinking agents, such as polyurethanes or polyurethane dispersions, polyacrylates, polyolefin dispersions, epoxysilanes, such as 3-glycidoxypropyltrialkoxysilane, and/or additives, such as e.g. imidazole or surface-active substances, can moreover be added to the solutions. Alkoxysilane hydrolysates, e.g. based on tetraethoxysilane, can furthermore be added to increase the scratch resistance in coatings or to increase the refractive index of the in situ layer in a controlled manner.

In the case where the precursors undergo chemical oxidative polymerization to give the conductive polymers, the presence of one or more oxidizing agents is necessary.

Oxidizing agents which can be used are all the metal salts known to the expert which are suitable for oxidative polymerization of thiophenes, anilines or pyrroles.

Suitable metal salts are metal salts of main group or sub-group metals, the latter also being called transition metal salts in the following, of the periodic table of the elements. Suitable transition metal salts are, in particular, salts of an inorganic or organic acid or inorganic acid containing organic radicals with transition metals, such as e.g. with iron(III), copper(II), chromium(VI), cerium(IV), manganese(IV), manganese(VII) and ruthenium(III).

Preferred transition metal salts are those of iron(III). Iron(III) salts are often inexpensive and easily obtainable and can be handled easily, such as e.g. the iron(III) salts of inorganic acids, such as, for example, iron(III) halides (e.g. FeCl₃) or iron(III) salts of other inorganic acids, such as Fe(ClO₄)₃ or Fe₂(SO₄)₃, and the iron(III) salts of organic acids and inorganic acids containing organic radicals.

Examples which may be mentioned of iron(III) salts of inorganic acids containing organic radicals are the iron(III) salts of the sulfuric acid monoesters of C₁-C₂₀-alkanols, e.g. the iron(III) salts of lauryl sulfate.

Particularly preferred transition metal salts are those of an organic acid, in particular iron(II) salts of organic acids.

Examples of iron(III) salts which may be mentioned are: the iron(III) salts of C₁-C₂₀-alkanesulfonic acids, such as methane-, ethane-, propane- or butanesulfonic acid or higher sulfonic acids, such as dodecanesulfonic acid, of aliphatic perfluorosulfonic acids, such as trifluoromethanesulfonic acid, perfluorobutanesulfonic acid or perfluorooctanesulfonic acid, of aliphatic C₁-C₂₀-carboxylic acids, such as 2-ethylhexylcarboxylic acid, of aliphatic perfluorocarboxylic acids, such as trifluoroacetic acid or perfluorooctanoic acid, and of aromatic sulfonic acids which are optionally substituted by C₁-C₂₀-alkyl groups, such as benzenesulfonic acid, o-toluenesulfonic acid, p-toluenesulfonic acid or dodecylbenzenesulfonic acid, and of cycloalkanesulfonic acids, such as camphorsulfonic acid.

Any desired mixtures of these abovementioned iron(III) salts of organic acids can also be employed.

The use of the iron(III) salts of organic acids and inorganic acids containing organic radicals has the great advantage that they do not have a corrosive action.

Iron(III) p-toluenesulfonate, iron(III) o-toluenesulfonate or a mixture of iron(III) p-toluenesulfonate and iron(II) o-toluenesulfonate are very particularly preferred as metal salts.

In preferred embodiments, the metal salts have been treated with an ion exchanger, preferably a basic anion exchanger, before their use. Examples of suitable ion exchangers are macroporous styrene and divinylbenzene polymers which have been functionalized with tertiary amines, such as are marketed e.g. under the trade name Lewatit® by Bayer A G, Leverkusen.

Oxidizing agents which are furthermore suitable are peroxo compounds, such as peroxodisulfates (persulfates), in particular ammonium and alkali metal peroxodisulfates, such as sodium and potassium peroxodisulfate, or alkali metal perborates—optionally in the presence of catalytic amounts of metal ions, such as iron, cobalt, nickel, molybdenum or vanadium ions—and transition metal oxides, such as e.g. pyrolusite (manganese(IV) oxide) or cerium(IV) oxide.

For the oxidative polymerization of the thiophenes of the formula (II), in theory 2.25 equivalents of oxidizing agent are required per mol of thiophene (see e.g. J. Polym. Sc. Part A Polymer Chemistry vol. 26, p. 1287 (1988)). However, lower or higher numbers of equivalents of oxidizing agent can also be employed. In the context of the invention, preferably one equivalent or more, particularly preferably 2 equivalents or more of oxidizing agent are employed per mol of thiophene.

The anions of the oxidizing agent used can preferably serve as counter-ions, so that in the case of chemically oxidative polymerization an addition of additional counter-ions is not absolutely necessary.

The oxidizing agents can be applied to the substrate together with or separately from the precursors—optionally in the form of solutions. If the precursors, oxidizing agents and optionally counter-ions are applied separately, the substrate is preferably first coated with the solution of the oxidizing agent and optionally the counter-ions and then with the solution of the precursors. In the case of the preferred joint application of thiophenes, oxidizing agent and optionally counter-ions, the oxide layer of the anode body is coated with only one solution, namely a solution containing thiophenes, oxidizing agent and optionally counter-ions. Possible solvents in all cases are those described above as suitable for the precursors.

The solution can moreover comprise as further components (binders, crosslinking agents etc.) the components already described above for the solutions of the precursors.

The solutions to be applied to the substrate preferably comprise 1 to 30 wt. % of the precursors, preferably of the thiophenes of the general formula (II), and optionally 0 to 50 wt. % of binders, crosslinking agents and/or additives, both percentages by weight being based on the total weight of the solution.

The solutions are applied by known processes, e.g. by spin-coating, impregnation, pouring, dripping, spraying, atomizing, knife-coating, brushing or printing, for example ink-jet, screen or tampon printing.

The removal of any solvent present after application of the solutions can take place by simple evaporation at room temperature. However, to achieve higher processing speeds it is more advantageous to remove the solvents at elevated temperatures, e.g. at temperatures from 20 to 300° C., preferably 40 to 250° C. An after-treatment with heat can be combined directly with the removal of the solvent or can also be carried out at a separate time from the production of the coating. The solvents can be removed before, during or after the polymerization.

The duration of the heat treatment can be 5 seconds to several hours, depending on the nature of the polymer used for the coating. Temperature profiles with different temperatures and dwell times can also be employed for the heat treatment.

The heat treatment can be carried out e.g. by moving the coated substrates through a heating chamber, which is at the desired temperature, at a speed such that the desired dwell time at the chosen temperature is achieved, or by bringing them into contact with a hot-plate, which is at the desired temperature, for the desired dwell time. The heat treatment can furthermore be carried out, for example, in a heating oven or several heating ovens each with different temperatures.

After removal of the solvents (drying) and if appropriate after the after-treatment with heat, it may be advantageous to wash the excess oxidizing agent and residual salts out of the layer with a suitable solvent, preferably water or alcohols. Residual salts here are to be understood as meaning the salts of the reduced form of the oxidizing agent and any further salts present.

The electrochemical polymerization can be carried out by processes known to the expert.

If the thiophenes of the general formula (II) are liquid, the electropolymerization can be carried out in the presence or absence of solvents which are inert under the electropolymerization conditions; the electropolymerization of solid thiophenes of the general formula (II) is carried out in the presence of solvents which are inert under the electrochemical polymerization conditions. In certain cases it may be advantageous to employ solvent mixtures and/or to add solubilizing agents (detergents) to the solvents.

Examples which may be mentioned of solvents which are inert under the electropolymerization conditions are: water; alcohols, such as methanol and ethanol; ketones, such as acetophenone; halogenated hydrocarbons, such as methylene chloride, chloroform, carbon tetrachloride and fluorohydrocarbons; esters such as ethyl acetate and butyl acetate; carbonic acid esters, such as propylene carbonate; aromatic hydrocarbons, such as benzene, toluene and xylene; aliphatic hydrocarbons, such as pentane, hexane, heptane and cyclohexane; nitriles, such as acetonitrile and benzonitrile; sulfoxides, such as dimethylsulfoxide; sulfones, such as dimethyl sulfone, phenyl methyl sulfone and sulfolane; liquid aliphatic amides, such as methylacetamide, dimethylacetamide, dimethylformamide, pyrrolidone, N-methylpyrrolidone and N-methylcaprolactam; aliphatic and mixed aliphatic-aromatic ethers, such as diethyl ether and anisole; liquid ureas, such as tetramethylurea; or N,N-dimethyl-imidazolidinone.

For the electropolymerization, electrolyte additions are added to the thiophenes of the general formula (II) or solutions thereof. Free acids or conventional conductive salts which have a certain solubility in the solvents used are preferably used as electrolyte additions. Electrolyte additions which have proved suitable are e.g.: free acids, such as p-toluenesulfonic acid and methanesulfonic acid, and furthermore salts with alkanesulfonate, aromatic sulfonate, tetrafluoroborate, hexafluorophosphate, perchlorate, hexafluoroantimonate, hexafluoroarsenate and hexachloroantimonate anions and alkali metal, alkaline earth metal or optionally alkylated ammonium, phosphonium, sulfonium and oxonium cations.

The concentrations of the monomeric thiophenes of the general formula (II) can be between 0.01 and 100 wt. % (100 wt. % only in the case of liquid thiophene); the concentrations are preferably 0.1 to 20 wt. %, based on the total weight of the solution.

The electropolymerization can be carried out discontinuously or continuously.

The current density for the electropolymerization can vary within wide limits; a current density of 0.0001 to 100 mA/cm², preferably 0.01 to 40 mA/cm² is conventionally used. A voltage of about 0.1 to 50 V is established at this current density.

Suitable counter-ions are those already mentioned above. In the electrochemical polymerization, these counter-ions can optionally be added to the solution or the thiophenes as electrolyte additions or conductive salts.

The electrochemical oxidative polymerization of the thiophenes of the general formula (II) can be carried out at a temperature from −78° C. up to the boiling point of the solvent optionally employed. The electrochemical polymerization is preferably carried out at a temperature from −78° C. to 250° C., particularly preferably −20° C. to 60° C.

The reaction times are preferably 1 minute to 24 hours, depending on the thiophene used, the electrolytes used, the temperature chosen and the current density applied.

In the electrochemical polymerization, the substrate, which as a rule is not conductive, is first coated with a thin transparent layer of a conductive polymer, as described in Groenendaal et al. Adv. Mat. 2003, 15, 855. The substrate coated with a conductive coating in this way, with a surface resistance of ≧10⁴ Ω/sq, takes over the function of the Pt electrode during the subsequent electropolymerization. The layer comprising the conductive polymer grows on top when a voltage is applied.

Since the conductive polymer(s) in the layer comprising at least one conductive polymer are produced directly by polymerization of precursors in situ on the substrate, this layer is also called the “in situ layer” in the following. The concept of in situ deposition of a conductive polymer from a polymerizable solution of monomer and oxidizing agent is generally known in technical circles.

A polymeric optical functional layer can be produced by the process according to the invention without involved and expensive CVD (Chemical Vapor Deposition), vapour deposition or sputtering processes being necessary. Inter alia, use of the process according to the invention over a large area is also rendered possible by this means. Furthermore, the in situ layer can be applied at low temperatures, preferably room temperature. The process according to the invention is thus also suitable for application to polymeric, flexible substrates which as a rule tolerate only low temperature processes and do not withstand the temperatures of thermal CVD or of reactive sputtering during deposition.

The optical functional layer according to the invention preferably has a transmission of Y≧25%. The transmission is determined by the measurement methods, such as is described in the specification ASTM D 1003-00. The transmission is then calculated in accordance with ASTM E 308 (light type C, 2*observers).

The polymeric layers according to the invention are outstandingly suitable as optical functional layers, such as antireflection layers on optical elements and glazing panes, heat insulation layers on glazing panes, cladding layers on glass fibers and interference layers on pearlescent pigments.

The preferred functional layer—comprising a polydioxythiophene—is distinguished by the particular course of its dispersion and absorption curve and is therefore particularly suitable as an optical functional layer. The dispersion curve describes the spectral dependence of the refraction index; the absorption curve describes the spectral dependence of the absorption constant.

Polymeric optical functional layers based on the layer according to the invention are of advantage in the following uses:

1.) Antireflection Layers on Surfaces (cf. Born, Max, Principles of Optics, p. 51 et seq.)

By application of a transparent functional layer, antireflection layers can be generated by depositing these layers in defined thicknesses. If the optical path length of this layer is equal to one quarter of the wavelength, i.e. n_{L}*d=λ/4, destructive interference of the two partial beams reflected on the upper and lower side of the layer occurs. If the reflected partial beams have the same intensity, in total no light is reflected. So that the reflected partial beams have the same intensity, the refractive index of the antireflection layer should be equal to the geometric mean of the refractive indices of air and the support, i.e. n_{L}=√(n_{A}*n_{S}) (cf. Born, Max p. 64 et seq.). Since n_{A}=1 and n_{S}=1.5 for glass, the refractive index of the antireflection layer applied should ideally be n_{L}=1.22.

Transparent inorganic materials, such as e.g. titanium dioxide, silicon dioxide, cryolite or magnesium fluoride, are conventionally deposited as a thin film as antireflection layers. All these inorganic layers have a refractive index which is significantly above the desired geometric refractive index of n=1.22. For example, the refractive index of cryolite is n=1.35, or that of MgF₂ is n=1.38. Transparent solids with a low refractive index of n<1.3 have not hitherto been used as antireflection layers.

Because the refractive index is too high, antireflection layers are therefore deposited e.g. on glass as multilayer systems. In this procedure, thin inorganic layers with a different refractive index are deposited on one another in alternating sequence, as described e.g. in U.S. Pat. No. 4,726,654.

The abovementioned inorganic antireflection layers are deposited by known, thin layer deposition processes, such as thermal vapour deposition, sputtering, CVD etc. These processes are involved and therefore expensive, since all require a vacuum and the deposition rates are slow.

It has been found, surprisingly, that by application of a layer comprising in situ PEDT to PET film or quartz glass, the reflection of a support in the visible spectral range can be significantly reduced. Since the layer comprising PEDT has a very low refractive index of n=0.8-1.3 in the visible spectral range with a simultaneously high transparency, a thin layer of this material can be used as an antireflection layer. The optical constants of a thin layer are determined by two known methods of thin layer optics by iterative fitting of the reflection and transmission curves of two layers of different layer thickness. In the first method, n and k are calculated iteratively with the aid of the Fresnel formulae. In the second method the ETA-RT apparatus of Steag Eta-Optik GmbH, Heinsberg, Germany and the software integrated therein are used to determine n and k. Both methods produce similar results.

The low refractive index in wide parts of the visible spectral region of the in situ layer according to the invention of n<1.3 has the following advantages:
a) The refractive index of the layer according to the invention can be adjusted—as has surprisingly been found—in a controlled manner such that this corresponds to the geometric mean of the refractive indices of air nA and the substrate ns. High antireflection effects can already be achieved with an individual layer in this way. The adjustment is made by mixing a certain amount of a polymer with a refractive index of n_{ISP}<n_{P} which is soluble in the in situ PEDT solution with the in situ PEDT solution. The refractive index of the layer n_{L} can then be easily calculated from:
   n_{L}=n_{ISP}*ρ_{ISP}+n_{P}*ρ_{P}
where n_{ISP} and n_{P} are the refractive indices of the pure in situ PEDT and the pure polymer layer respectively and ρ_{ISP} and ρ_{P} are the corresponding volume contents. Suitable polymers with n_{ISP}<n_{P} and an adequate solubility in an in situ PEDT solution are described above in more detail.
b) The layer comprising in situ PEDT can be applied very much more easily to the desired support from solution by employing inexpensive deposition processes—as described above in more detail.
   2.) Coating Layer on Effect Pigments

Coated mica platelets are used as pearlescent effect pigments for coloring lacquers (cf. Iridin® pigments, Merck, Darmstadt). The pearlescent effect is produced by a thin layer which is precipitated on to the mica carrier. As described above under 1.), an interference phenomenon also occurs here. Certain regions of the visible spectral range are preferentially reflected or absorbed, and as a result the particular color impression is formed.

These pigments are conventionally coated with inorganic layers, such as e.g. TiO₂ or SiO₂. Because of the low refractive index and its unique spectral course, a thin layer of PEDT enables a colored pigment with new improved properties to be prepared.

3.) Infrared Reflection Layer on Surfaces

The heating up of closed rooms behind panes of glass through which sunlight can penetrate can be reduced by providing the panes of glass with an infrared-reflecting protective layer (IR reflection layer). Since this layer at the same time should be transparent in the visible spectral range, inorganic coatings, such as indium tin oxide (ITO) or antimony tin oxide are conventionally used as an IR reflection layer for panes of glass (cf. K glass).

It has been found, surprisingly, that by application of a layer comprising in situ PEDT to PET film or quartz glass, the IR reflection of the carrier in the wavelength range of the thermal radiation of the sun, i.e. in the range of λ>750 nm, can be increased significantly. As a result, less IR light is allowed through and the warming up of the room behind the pane can be reduced.

4.) Wave Conductor, Cladding of Glass Fibers

Optical glass fibers are coated with a cladding layer (cf. Bergmann Schaefer, volume 3 Optik, p. 449 et seq., 9th edition) to protect the sensitive surface of the glass fibers against scratching. For this, in the case of glass fibers the outer region of the glass fiber is suitably doped, i.e. provided with impurities in a controlled manner, in order to lower the refractive index in the relevant spectral transition range relative to the inside of the fiber. The signal remains, due to this refractive index gradient and the associated total reflection, inside the fiber and disturbances on the surface, such as e.g. scratches, no longer act as scattering centers.

The process described above of doping glass in the outer region has the disadvantage that this process can be realized only during production of the glass fiber. The region of total reflection is thereby limited to a relatively narrow wavelength range.

Because of the low refractive index of in situ PEDT, this material is also suitable as a cladding layer for glass fibers, with the advantage that this layer can also still be applied subsequently and easily to the glass or polymer light conductor fibers and total reflection is retained in wide regions in the visible and IR range.

The effect found is unexpected, since no polymers which can be applied from solution and have a refractive index of n<1.3 in the visible spectral range, or high reflection properties for wavelengths in the near infrared were known hitherto.

### BRIEF DESCRIPTION OF THE DRAWINGS

The invention is explained in the following by way of example by means of the figures.

The figures show:

FIG. 1A graph which shows the reflection of an in situ PEDT layer on a quartz substrate as a function of the wavelength in comparison with a layer merely of quartz,

FIG. 2 a graph similar to FIG. 1 with a layer comprising poly-3,4-ethylene-dioxythiophene and polysulfonic acid,

FIG. 3 a graph similar to FIG. 1 for the measurement on in situ coated and non-coated PET film,

FIG. 4 a further graph similar to FIG. 3.

### EXAMPLES

### Example 1

In Situ PEDT Layers on Quartz Glass:

Epoxysilane (Silquest® A187, manufacturer OSi specialities), diluted with 20 parts of 2-propanol, is spun-coated on to cleaned quartz substrates with a spin-coater and then dried at 50° C. for 5 min in air. The layer thicknesses are less than 20 nm. A solution comprising 3,4-ethylenedioxythiophene (Baytron® M), a 6% strength solution of iron(III) (tosylate)₃ in butanol (Baytron® CB 40, manufacturer H. C. Starck GmbH), and imidazole in a wt. ratio of 1:20:0.5 is prepared and filtered (Millipore HV, 0.45 μm). Thereafter, the solution is spun-coated with a spin-coater at 1,000 rpm on to the quartz substrates coated with epoxysilane. The layer is subsequently dried at room temperature (RT, 23° C.) and then rinsed thoroughly with dist. water in order to remove the iron salts. After drying of the layers, the layer thickness is approx. 155 nm at 1,000 rpm. The layers have smooth surfaces with a surface roughness Sr of <5 nm. The conductivity of the layers is 550 S/cm. The transparency of the layers is high. Thus, the transparency Y of a layer 200 nm thick on the glass substrate is >50%.

The reflection spectra of the layers on quartz are recorded with a spectrophotometer (Perkin-Elmer Lamda 900, equipped with an Ulbricht globe) in accordance with DIN 5036. FIG. 1 shows the reflection spectra. It can be clearly seen that the reflection in wide parts of the visible spectral range is lower than that of non-coated quartz glass. At 550 nm in particular, the maximum of the sensitivity curve of the eye, the reflection of the 155 nm thick in situ PEDT layer on quartz is only 1.4%, compared with 6.8% for non-coated quartz. The in situ PEDT layer therefore leads to antireflection of the quartz substrate in the visible spectral range.

At a wavelength of 2,000 nm the reflection in the in situ PEDT layer on quartz is 51.5%, compared with 6.1% on non-coated quartz. The in situ PEDT layer thus reflects in the near IR range to a greater degree than the quartz substrate.

### Example 2

Baytron P® AI4071 Layers on Quartz Glass:

A mixture of poly(3,4-ethylenedioxythiophene) and polystyrenesulfonic acid (1:2.5 parts by wt.) Baytron P® AI4071 is spun-coated at 1,000 rpm on to cleaned quartz substrates. The layer is then dried at 200° C. After drying of the layers, the layer thickness is approx. 180 nm. The layers have smooth surfaces with a surface roughness Sr of <5 nm. The conductivity of the layers is 0.1 S/cm.

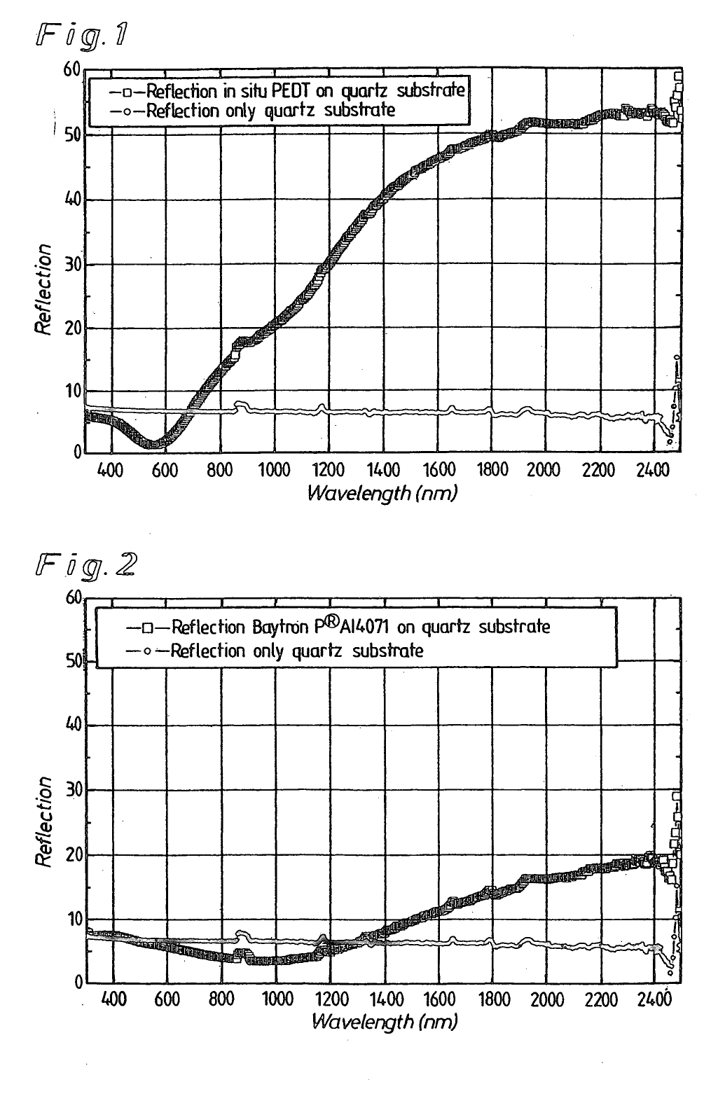

The reflection spectra are shown in FIG. 2.

At a wavelength of 700 nm the reflection of the Baytron P® AI4071 layer on quartz is 4.8%, compared with 6.7% in the case of non-coated quartz. The Baytron P® AI4071 layer therefore leads to an antireflection of the quartz substrate in the visible spectral range.

At a wavelength of 2,000 nm the reflection of the Baytron P® AI4071 layer on quartz is 16.2%, compared with 6.1% in the case of non-coated quartz. The Baytron P® AI4071 layer thus reflects in the near IR range to a greater degree than the quartz substrate.

### Example 3

As in example 1, an in situ PEDT layer is deposited on quartz glass and the reflection and transmission spectra are measured, with the difference that the speed of revolution is 2,000 rpm and the layer thickness is 95 nm.

### Example 4

As in example 2, a Baytron P® AI4071 layer is deposited on quartz glass and the reflection and transmission spectra are measured, with the difference that the speed of revolution is 2,000 rpm and the layer thickness is 100 nm.

### Example 5

With the layers produced according to example 1 and 3 and example 2 and 4, the dispersion and absorption curves of the in situ PEDT layer and of the Baytron P® AI4071 layer on quartz glass are determined. The determination is carried out with two different methods, which produce results which are in agreement. Method 1 is a computer program which is based on the Fresnel formulae and fits the n and k iteratively until the calculated R and T courses correspond to those measured on the two specimens of different layer thickness. Method 2 uses the ETA-RT apparatus of Steag EtaOptik, with which n and k can be determined from R and T spectra of thin layers on a substrate. The two methods produce a similar result, which is summarized in table 1 of the appendix.

It follows from table 1 that an in situ PEDT layer has a refractive index of n<1.3 in wide parts of the visible spectral ranges, whereas a Baytron P® AI4701 layer—which, with the PSS, comprises an electrically non-conductive component—has a higher refractive index.

TABLE 1
Dispersion and absorption curves of in situ PEDT and Baytron P AI4071

| | |
|---|---|
| AI4071 | in situ PEDT |

| λ (nm) | n | k | n | k |
|---|---|---|---|---|
| 350 | 1.515 | 0.016 | 1.4825 | 0.0485 |
| 400 | 1.495 | 0.019 | 1.3945 | 0.069 |
| 450 | 1.477 | 0.023 | 1.316 | 0.1005 |
| 500 | 1.460 | 0.028 | 1.245 | 0.1435 |
| 550 | 1.446 | 0.035 | 1.182 | 0.1975 |
| 600 | 1.432 | 0.044 | 1.1255 | 0.262 |
| 650 | 1.420 | 0.053 | 1.081 | 0.3385 |
| 700 | 1.410 | 0.064 | 1.044 | 0.425 |
| 750 | 1.400 | 0.076 | 1.014 | 0.523 |
| 800 | 1.392 | 0.089 | 0.9915 | 0.632 |
| 850 | 1.385 | 0.105 | | |

### Example 6

As in example 1, an in situ PEDT layer is deposited and measured, with the difference that the solution comprising Baytron® M, Baytron® CB 40 and DMSO in a wt. ratio of 1:20:1.25 is prepared and this solution is applied to PET film with a doctor blade. The doctor blade used leads to a wet layer thickness of d=12 μm.

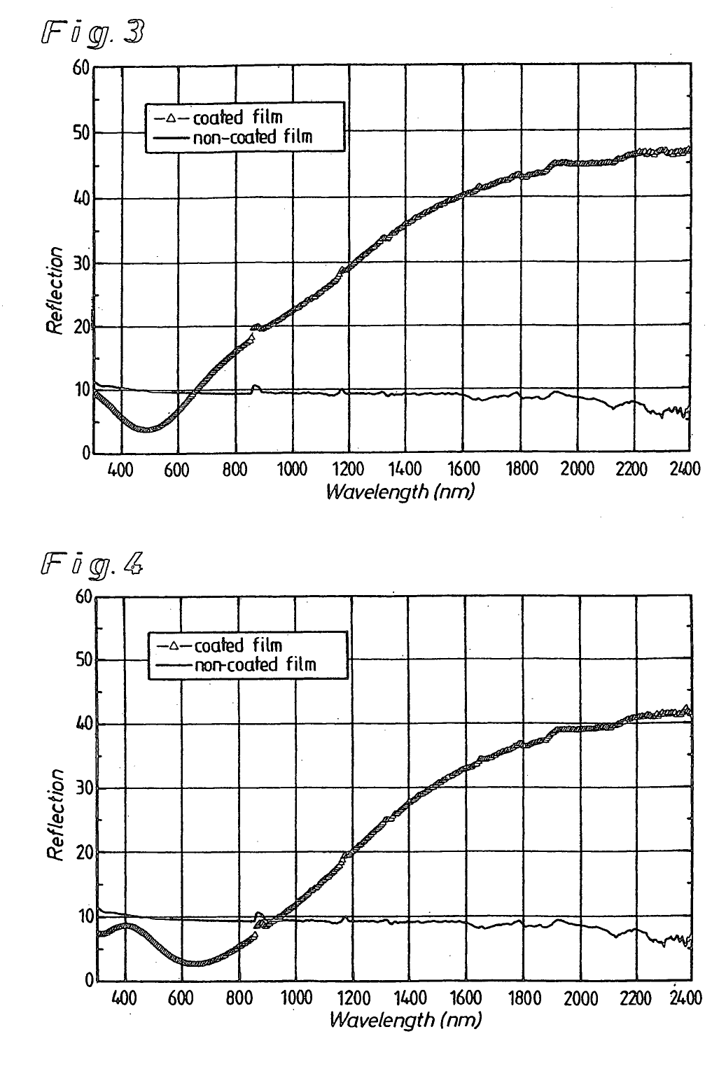

The reflection spectra of the film coated in this way are shown in FIG. 3 of the appendix in comparison with non-coated PET film.

The reflection is significantly lower in the visible spectral range with the coating than without a coating. Thus, the reflection at 490 nm R=3.62% with the coating, compared with R=9.9% without a coating. In the near IR, on the other hand, the reflection is higher with the coating, thus the reflection at 2,400 nm R=46.9% with the coating, compared with R=6.5% without a coating.

This shows that the layer according to the invention leads to a reduction of the reflection in the visible spectral range and to an increase in the reflection in the near IR.

### Example 7

As in example 1, an in situ PEDT layer is deposited and measured, with the difference that the solution comprising Baytron® M, Baytron® CB 40, DMSO and a polyurethane-based crosslinking agent Desmotherm® 2170 (manufacturer Bayer AG) in a wt. ratio of 1:20:1.25:0.5 is prepared and this solution is applied to PET film with a doctor blade. The doctor blade used leads to a wet layer thickness of d=12 μm.

The reflection spectra of the film coated in this way are shown in FIG. 4 of the appendix in comparison with non-coated PET film.

The reflection is significantly lower in the visible spectral range with the coating than without a coating. Thus, the reflection at 650 nm R=2.60% with the coating, compared with R=9.5% without a coating. In the near IR, on the other hand, the reflection is higher with the coating, thus the reflection at 2,400 nm R=41.5% with the coating, compared with R=6.5% without a coating.

This shows that the layer according to the invention leads to a reduction of the reflection in the visible spectral range and to an increase in the reflection in the near IR. This example furthermore shows in particular, in comparison with example 6, that the spectral course of the reflection can be changed by the addition of the crosslinking agent Desmotherm 2170 under the same deposition conditions.

1. Transparent optical functional layer, having a refractive index of n<1.3 in parts of the visible spectral range and comprising at least one electrically conductive polymer which comprises at least one polythiophene with recurring units of the formula (I) 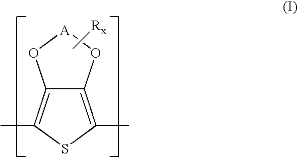
wherein
A represents an optionally substituted C₁-C₅-alkylene radical,
R represents a linear or branched, optionally substituted C₁-C₁₈-alkyl radical, an optionally substituted C₅-C₁₂-cycloalkyl radical, an optionally substituted C₆-C₁₄-aryl radical, an optionally substituted C₇-C₁₈-aralkyl radical, an optionally substituted C₁-C₄-hydroxyalkyl radical or a hydroxyl radical,
x represents an integer from 0 to 8 and
when x is greater than 1, the radicals R bonded to A can be identical or different, or represent polyaniline or polystyrene.

2. Transparent optical functional layer according to claim 1, wherein said conductive polymer is a polythiophene with recurring units of the formula (I).

3. Transparent optical functional layer according to claim 1, wherein A represents an optionally substituted C₂-C₃-alkylene radical and x represents 0 or 1.

4. Transparent optical functional layer according to claim 1, wherein the polythiophene with recurring units of the general formula (I) is poly(3,4-ethylenedioxythiophene).

5. Transparent optical functional layer according to claim 1, further comprising a polymeric anion which is an anion of a polymeric carboxylic or sulfonic acid.

6. Transparent optical functional layer according to claim 5, wherein said polymeric anion is an anion of polystyrenesulfonic acid.

7. Transparent optical functional layer according to claim 1, having a transmission, measured in accordance with ASTM D 1003-00 in combination with ASTM E 308, of Y≧25%.

8. Process for the production of a transparent optical functional layer of claim 1 on a substrate, which comprises applying to said substrate a thiophene corresponding to the formula (II) 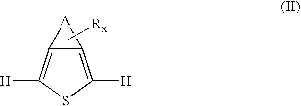
in which A, R and x have the meaning given for formula (I) in claim 1, optionally in the form of solutions, and conducting a chemical oxidative polymerization of the same in the presence of one or more oxidizing agents, or carrying out an electrochemical polymerization, to give the conductive polymers.

9. Process according to claim 8, wherein the substrate is treated with an adhesion promoter before application of the layer comprising at least one conductive polymer.

10. An optical construction having a transparent optical functional layer of claim 1.

11. An antireflection layer on a surface, said antireflection layer comprising the transparent optical functional layer of claim 1.

12. Effect pigments comprising a coating layer of the transparent optical functional layer of claim 1.

13. An infrared reflection layer on a surface, said infrared reflection layer being a transparent optical functional layer of claim 1.

14. A cladding layer on optical glass fibers, said cladding layer being comprised of the transparent optical functional layer of claim 1.
